(19) United States
(12) Patent Application Publication
(10) Pub. No.: US 2010/0045276 A1
(43) Pub. Date: Feb. 25, 2010

(54) Eddy current inspection system

(75) Inventors: Satish Udpa, Okemos, MI (US); Lalita Udpa, Okemos, MI (US); Naveen V. Nair, East Lansing, MI (US); Vikram Reddy Melapudi, East Lansing, MI (US)

Correspondence Address: HARNESS, DICKEY & PIERCE, P.L.C., P.O. BOX 828, BLOOMFIELD HILLS, MI, 48303, US

(73) Assignee: Board of Trustees of Michigan State University, East Lansing, MI (US)

(21) Appl. No.: 12/011,208

(22) Filed: Jan. 24, 2008

Related U.S. Application Data
(60) Provisional application No. 60/897,402, filed on Jan. 25, 2007.

(51) Int. Cl. G01R 33/18; G01R 33/02

(52) U.S. Cl. 324/209; 324/248

(57) ABSTRACT

An innovative method is provided for assessing structural integrity of a sample. The method comprises: capturing a signal indicative of magnetic flux density caused by an Eddy current flowing in the sample; extracting an envelope of the captured signal using a demodulation scheme; sampling the envelope at a frequency that is lower than the frequency of the excitation current signal which generated the Eddy current; and examining the sampled envelope to assess structural integrity of the sample.

### GOVERNMENT RIGHTS

The U.S. Government may have a paid-up license in this invention, and may have the right, in limited circumstances, to require the patent owner to license others on reasonable terms as identified by the terms of Federal Grant No. 05-S508-019-C1 awarded by the Air Force Research Lab.

### FIELD

The present disclosure relates to a technique for assessing the structural integrity of a structure and an inspection system for implementing the same.

### BACKGROUND

Eddy current testing has been used as the primary nondestructive evaluation technique in the aircraft industry for more than fifty years. Though the technique is powerful in principle, the inspection process is often time consuming since the impedance plane signal returned by the probe is difficult to interpret and often requires special operator training.

Magnetooptic imaging (MOI) was proposed as a possible solution to the problem several years ago. In this scheme, a copper foil is used as a sheet current source to induce eddy currents in the test specimen. When there are no anomalies present in the specimen, the normal component of the field near the center of the current source vanishes. However, in the presence of a defect, a normal component exists and is imaged using the Faraday rotation effect. The MOI system returns an analog image of this magnetic field. The lack of any special processing requirements makes this system extremely fast and simple to use. The primary disadvantage of this technique is the lack of quantitative measure of the field. Alternative approaches are needed in applications where a quantitative measure of the field is desired.

This disclosure describes an inspection system that combines the advantages of MOI with a quantitative field measurement. The statements in this section merely provide background information related to the present disclosure and may not constitute prior art.

### SUMMARY

An innovative method is provided for assessing structural integrity of a sample. The method comprises: capturing a signal indicative of magnetic flux density caused by an Eddy current flowing in the sample; extracting an envelope of the captured signal using a demodulation scheme; sampling the envelope at a frequency that is lower than the frequency of the excitation current signal which generated the Eddy current; and examining the sampled envelope to assess structural integrity of the sample.

In another aspect of this method, moving a probe at different speeds while sampling the envelope extracted through demodulation at a fixed frequency provides different spatial resolution of the sample.

Further areas of applicability will become apparent from the description provided herein. It should be understood that the description and specific examples are intended for purposes of illustration only and are not intended to limit the scope of the present disclosure.

### DRAWINGS

FIG. 1 is a flow diagram illustrating an innovative technique for assessing the structural integrity of a sample structure;

FIG. 2 is a diagram which depicts an exemplary inspection system for implementing the technique described in this disclosure;

FIG. 3 is a diagram of an exemplary flat coil excitation current sheet;

FIG. 4 is a schematic of an exemplary in-phase/quadrature (I/Q) detection scheme which may be employed in the inspection system;

FIG. 5 is a graph comparing signals obtained using the I/Q detection scheme in relation to the traditional scheme;

FIGS. 6A and 6B illustrate a test specimen geometry from a top view and side view, respectively;

FIG. 7 is a graph comparing model results and experimental results obtained using the proposed inspection system; and

FIG. 8 illustrates an exemplary scan image generated using the proposed inspection system.

The drawings described herein are for illustration purposes only and are not intended to limit the scope of the present disclosure in any way.

### DETAILED DESCRIPTION

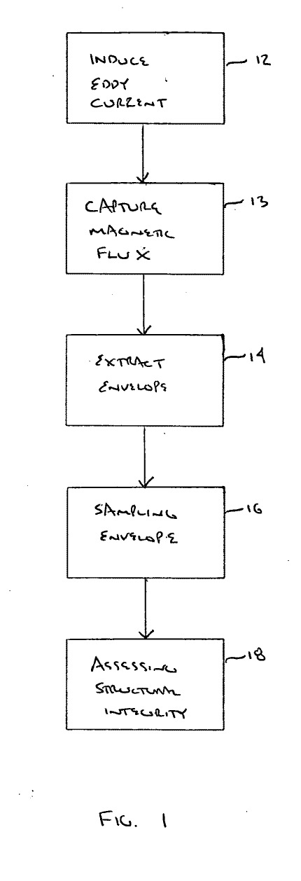

FIG. 1 illustrates an innovative technique for assessing the structural integrity of a sample structure. First, an Eddy current is induced in the sample at 12 using an excitation current signal having a relatively high frequency. When an excitation sheet, carrying multiple parallel line currents, is placed above a conducting medium, parallel eddy currents are induced on the surface of the conducting medium. Due to the symmetry of the current flow, the normal component of magnetic field is zero along the line of symmetry. The depth to which such eddy current patterns are formed, called the skin depth, is a function of the frequency of the impressed currents and the conductivity and permeability of the substrate. The flow of eddy currents is similar to that of the impressed currents in the excitation sheet. In the presence of a defect, the eddy current flow is impeded and forced to take an alternative path. This causes an asymmetry in the current distribution and thus a normal component of magnetic field, which we will call the leakage field, exists along the line of symmetry.

To detect defects in the sample, a signal indicative of magnetic flux density is captured at 13 near the surface of the sample. An envelope of the captured signal is then extracted at 14 by a demodulation process. The demodulation process allows the extracted signal to be sampled 16 at a frequency that is substantially lower than the frequency of the excitation current. This approach leads directly to measurement of the amplitude and phase information with very little computational effort.

Lastly, the sampled signal is examined at 18 to assess the structural integrity of the sample. Amplitude differences or ratios between an envelope of the excitation current signal and the envelope of the captured signal are indicative of the structural integrity of the sample. When the excitation signal is kept constant during the inspection process, then the amplitude of the captured signal alone can be used to infer the integrity of the sample under test. This technique is further understood from the description provided below

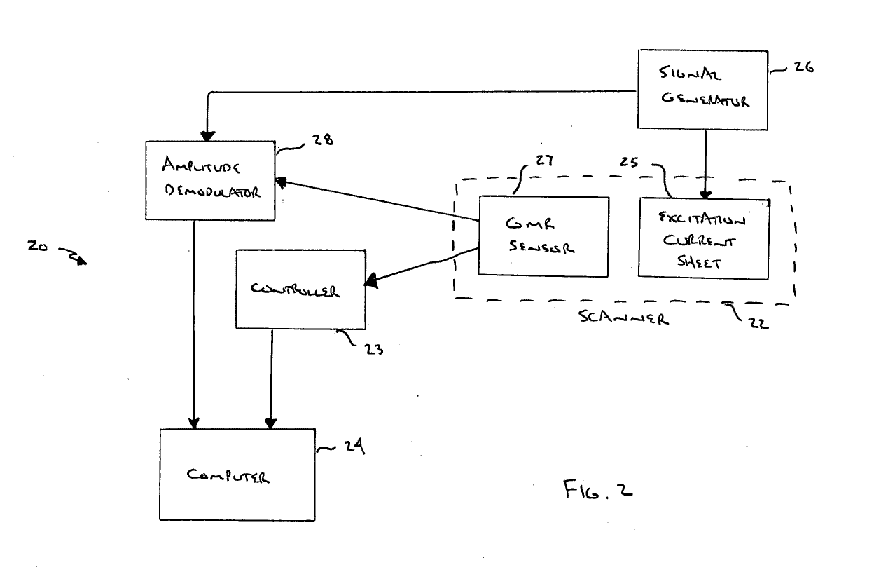

FIG. 2 depicts an exemplary inspection system 20 for implementing the technique described above. The inspection system 20 is generally comprised of a scanner 22 that interfaces through controller 23 to a computer 24 which serves as a signal processor. In an exemplary embodiment, the scanner 22 further includes an excitation current sheet 25 driven by a signal generator 26 and a giant magnetoresistive (GMR) sensor 27. Signals from the GMR sensor are processing by an analog demodulator 28 before being input into the computer 24. The computer 24 is preferably equipped with a display or another type of device which may be used to output scan images from the inspection system. Each of these components is further described below.

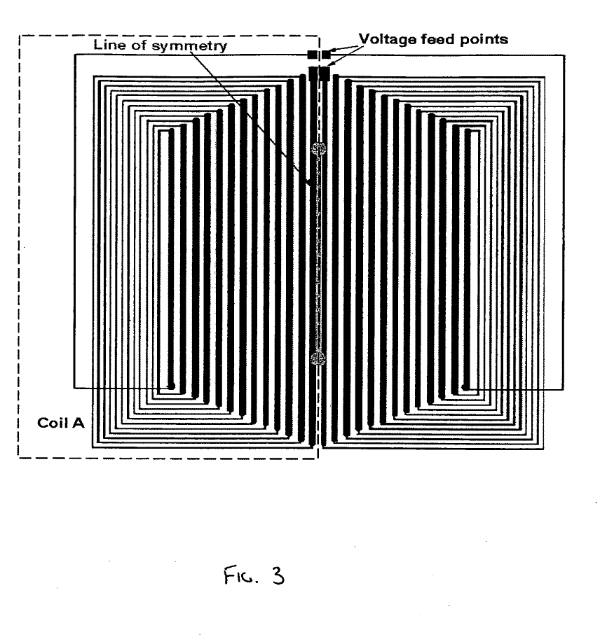

An excitation current sheet may serve as the source of eddy current in the exemplary inspection system. Ideally, it is preferred to have a current sheet with infinite area, infinitesimal thickness and a uniform current density. However, such a system is not practical. A realistic setup is an excitation sheet of finite area and thickness with uniform current density. Constructing such a system using plain copper sheets is not feasible because of the varying resistances of different current paths between the points of potential difference. FIG. 3 shows an exemplary excitation current sheet 25 employed to obtain uniformly distributed current density in proposed inspection system 20. It is important to observe that the structure enclosed within the dotted box in FIG. 3 is a flat spiral coil, labeled as coil A. Since the individual current lines of coil A along y-axis behave as resistances in series (as opposed to a sheet of copper, where they would be in parallel), the current flowing through each y-axis current line of coil A are equal. Coil B is the mirror image of coil A placed about symmetric axis C-D. In the exemplary implementation, a Textronix AFG320 arbitrary function generator was used as the signal generator 26 to generate a continuous sinusoidal signal at the desired frequency and then amplified using a CROWN PS-200 audio amplifier. The amplified current is fed to the excitation sheet. Other current sources and excitation structures can be employed to similar effect. Likewise, it is readily understood that other configurations for the excitation current sheet are within the scope of this disclosure.

Giant magnetoresistive (GMR) sensors may be employed to measure the magnetic flux density created by the Eddy current in the sample. The GMR sensor is an instantaneous field sensor that measures the magnetic flux density at each point in space (and time), as opposed to a spatially integrated quantity (as in the case of a traditional eddy current sensor). Unlike MOI, a major advantage of using a GMR-based sensor is the availability of the actual field information on a point-by-point basis. Since the GMR sensor returns the instantaneous value of the flux density, the proposed inspection system can measure the full complex, sinusoidal field. This field, most often, is at the same frequency of the excitation current with difference in phase and amplitude.

The GMR-based sensors, however, are unipolar in nature and therefore, do not allow for measurement of bipolar signals. In addition, these sensors have a nonlinear response at very low field values. These problems can be addressed by carefully calibrating and biasing the sensor prior to measurement. By biasing the coil using a dc field, the sensor can be made to work both in its linear range (around the bias field) and in a bipolar manner. The biasing is carrier out using a coil wound around the sensor. A dc current of varying amplitude is then passed through this coil to calibrate the sensor. Following calibration, the current required for biasing the sensor is determine from a calibration curve. Subsequently, this dc current is passed through the coil to maintain the sensor bias to allow for measurement of bipolar fields. This calibration scheme allows for reliable quantitative measurement of sinusoidal field measurements.

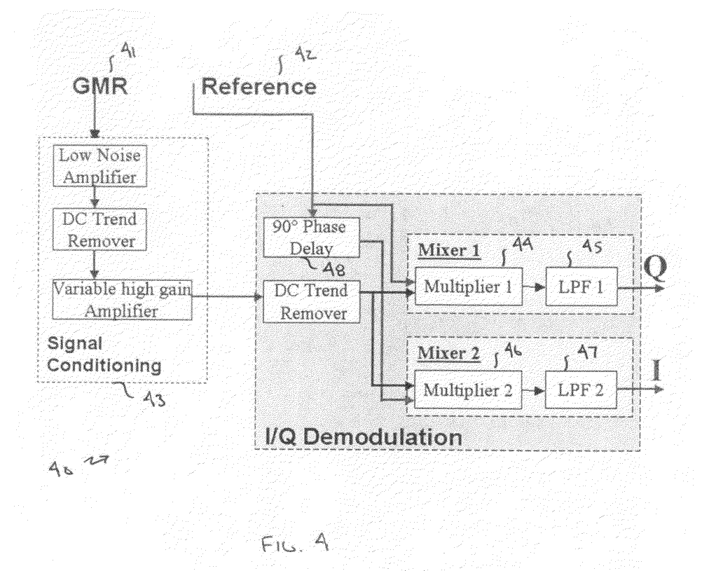

FIG. 4 is a schematic of an exemplary in-phase/quadrature (I/Q) detection scheme 40 which may be used to demodulate the incoming signal 41 from the GMR sensor. The I/Q detector also receives a reference signal 42 which correlates to the excitation signal applied to the current sheet. The I/Q detection circuit 40 utilizes a pair of analog multipliers 44, 46 and low-pass filters 45, 47 to extract the amplitude of the signal and its phase. To compute amplitude, the reference signal 42 undergoes a 90 degree phase delay 48 before being input to the applicable multiplier 51. The GMR signal 41 contains noise and therefore preferably undergoes signal conditioning to amplify and reduce the noise content. The conditioning improves the signal-to-noise ratio (SNR) of the GMR signal. GMR signals also usually have a high DC bias which is compensated at this stage. The amplified signal may further be passed through a low pass filter to further improve the signal. The I/Q detector is preferably implemented in analog circuitry. However, it is readily understood that other amplitude demodulation scheme that recovers a baseband signal in in-phase and quadrature form are also within the scope of this disclosure.

The use of an analog demodulation scheme offer several advantages over the traditional direct sampling scheme. For instance, the signal acquired in this scheme can be sampled at extremely low frequencies in comparison to the sampling rates required for a standard scheme, thus allowing for considerable speeding up of the data acquisition process. Since in a traditional scan, one needs to stop at each sample point and collect data, the reduction in acquisition time, when using the I/Q detection scheme, increases linearly with increase in the scan area for a given spatial resolution.

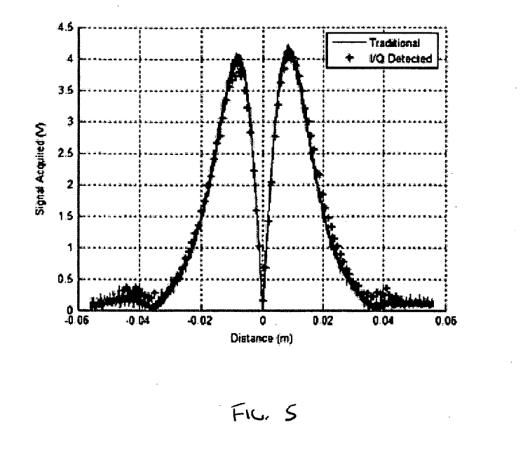

Furthermore, because the traditional acquisition scheme requires the scanner to stop at each sample point, the maximum scan resolution is limited by the resolution of the scanner. In an I/Q scheme, however, data is collected in an analog manner, and therefore, is not limited by the spatial resolution of the scanner used. FIG. 5 shows signals obtained by scanning a 10-mm though-hole in a 2.5 mm-thick aluminum plate using traditional and I/Q schemes. The scanning speed that was used for the I/Q detection scheme was 10 mm/s; whereas in the traditional case, the scanning was done at a spatial resolution of 1 mm on a point-by-point basis with the scanner held stationary for 50 cycles of the excitation waveform at each point to allow for settling. It is important to note that this implies an additional delay of 50 ms per sample point in traditional scanning. It can clearly be seen that the I/Q detection scheme allows for a much finer spatial sampling of the test specimen. It is also important to note here that in a standard NDE setting for an aircraft wing structure, involving several square meters of area to be inspected, the gain in time of 50 ms per sample point becomes quite significant. While this disclosure makes reference to aircraft structures, it is readily understood the inventive concept is applicable to other structure types.

A finite-element (FE) model was constructed to validate the feasibility of using the GMR-based system for defect detection. The three-dimensional (3-D) FR model is based on the A-V formulation, where A and V stand for the magnetic vector potential and the electric scalar potential, respectively. The governing equations for time-varying harmonic fields written in potential forms are

$$\begin{matrix}∇ \times \frac{1}{μ} ∇ \times A + jωσ A + σ ∇ V = 0 in {Ω}_{1} & ( 1 ) \\ ∇ \cdot ( jωσ A + σ ∇ V ) = 0 in {Ω}_{1} & ( 2 ) \\ ∇ \times \frac{1}{μ} ∇ \times A = {J}_{s} in {Ω}_{2} & ( 3 )\end{matrix}$$

where Ω₁ and Ω₂ are partitions of the solution domain with Ω₁ and Ω₂ denoting the eddy current region and the surrounding free space, respectively; A is used in both Ω₁ and Ω₂, while V is used in Ω₁ only. ω is the angular frequency of excitation, μ and σ are the permeability and conductivity of the media, respectively.

Expanding the potentials in terms of shape functions, applying the Galerkin technique for solving and imposing appropriate boundary conditions result in a system of algebraic equations. These equations are solved using either direct or iterative technique for determining the potential values. Physical quantities of interest, such as the magnetic flux density B (curl of A) are then calculated from the calculated values of A.

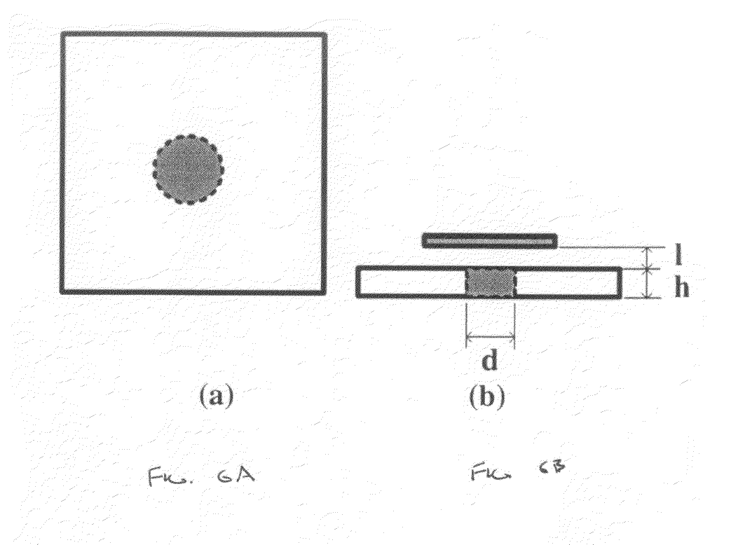

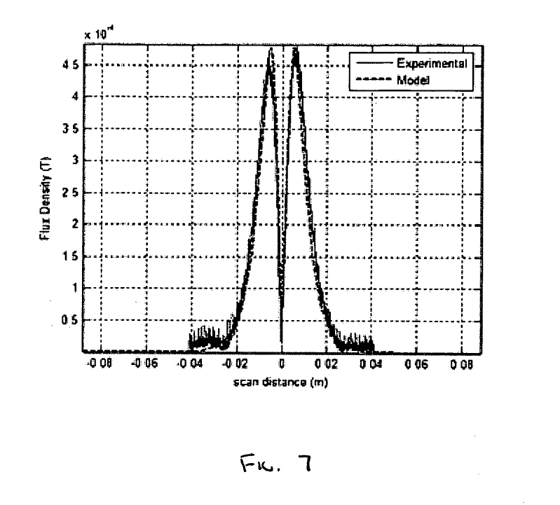

An exemplary specimen geometry test is shown in FIGS. 6A and 6B. The sample is a large 2.5-mm-thick (300 mm by 300 mm) single-layer aluminum (A1) plate with a 10-mm-diameter circular hole in the center. If the sample plate is sufficiently large, the edge effects can be neglected, and the geometry can be approximated by an infinite plate. Similarly, if the GMR sensor is held stationary with respect to the source (so that there is no relative motion between the sensor and source), the excitation source can be approximated by an infinite current sheet. The liftoff between the current sheet and A1 plate is 0.5 mm. The excitation frequency is set at 1 kHz, and the magnetic field is measure 3.8 mm above the sample plate at the location of the GMR sensor. The signal from the demodulator is sampled at 100 Hz. FIG. 7 shows a qualitative comparison between the model results and the experimental data.

The inspection system can take advantage of the fact that the incoming signal from the GMR sensor can be demodulated to extract only the envelope of the signal without loss of amplitude and phase information. This gives rise to two distinct advantages: (a) the signal envelope, from the demodulation circuit needs to be captured at a frequency much lower than the excitation frequency used in the conventional GMR systems and (b) any change in envelope of the signal is due to the spatial variation of the material properties of the sample under the probe. Thus the rate at which the envelope is expected to change can be determined by the expected rate of change in the material properties of the sample. More importantly, this also means that, if the speed of scanning the sample surface is kept constant, the time rate at which the envelope signal is sampled directly corresponds to the spatial resolution of the scan. Thus, the use of an analog demodulation scheme to extract the envelope, leading to an almost instantaneous measurement of amplitude and phase, results in a “real time” inspection system. The above facts are central to this disclosure and lead to two important conclusions, which translate into significant advantages over any previously conceived systems. First, the scanning system of this disclosure can yield an extremely high spatial resolution that is completely independent of the resolution of the scanner under question. Second, for comparable scanning resolutions, the sampling (and therefore, storage and processing) loads on the system are significantly lower than the currently available systems.

Sampling the envelope at a higher rate means higher spatial resolutions for a probe being moved at constant speed. This same concept can be applied in reverse, that is, for a fixed sampling rate, a higher spatial resolution can be achieved by simply moving the scanner at a lower speed. This idea is the major theme of this work and is applied to develop a novel and more intuitive scanning methodology that will be henceforth referred to as the “free scan system”. The idea again is that moving a probe at different speeds while sampling the envelope (extracted through demodulation) at a fixed frequency provides different spatial resolution. Therefore, when a user wants to inspect a region at higher resolution, it can be achieved by simply reducing the probe speed around that region. Combining this with the real-time feature gives a different and new scan modality. The term “free scan” is used to refer to the idea of not requiring movement of the sensor through a specific, pre-determined and restrictive path or set of points to form a scan image i.e. the user can simply move the probe in arbitrary fashion to generate scan image. The free scan idea is much more intuitive and user-friendly than a traditional scan typically implemented using an automated scanner.

With continued reference to FIG. 2, the scanner 22 is easily moveable (by hand) and provides means to measure and report accurate position information. A true free scan inspection system would require only a sensor to relay position and orientation data. However, a traditional X-Y scanner, without the driving motors to allow free motion by human hand, was adopted in this work. The scanner was equipped with instrumentation capable of providing the sensor's coordinates. Such a system actually proved advantageous in terms of (a) high position accuracy and (b) robust scanning setup. An exemplary scanner is the Parker-Daedal system with a resolution up to five microns (5 μm). Other types of scanners are contemplated for the proposed inspection system.

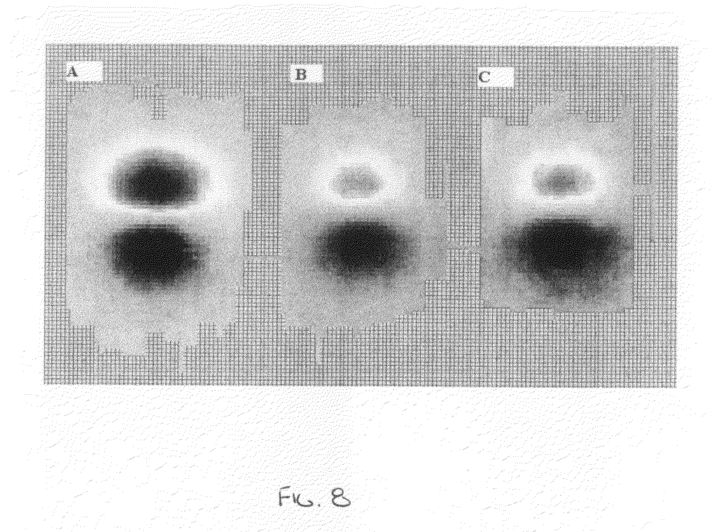

FIG. 8 illustrates a few of the advantages offered with the proposed free scan inspection system. The image wa generated by moving the scanner by hand over areas of interest (i.e., rivet regions A, B and C in the experimental sample plate). Region B shows a rivet with no defects; whereas, regions A and C are rivets with longer and smaller cracks, respectively. It is evident that the regions of interest scanned for individual rivets were determined only by the extent of leakage field, this leads to different sized scan images based on the variation in rivet regions. Unlike the proposed free scan inspection system, a conventional system based on automated scanner would require scanning the entire region encompassing A, B and C, which would require a lot more time and data storage.

A software interface is employed to coordinate communication between various constituent units of the proposed inspection system 20. An important aspect of the software is the protocol for data acquisition and display. The protocol adopted in the prototype was designed to aid in real-time scanning without loss of data. Two advanced user options introduced in this software are (a) region of interest (ROI) scans (b) “fill and filter” processing tool. These tools are introduced to enhance the performance and “experience” of the free-scan concept.

ROI scan feature allow a user to choose a particular area of interest (ROI), in a large scanned image, and scan that area at any desired spatial resolution. This allows the user to (a) focus attention on a particular area and (b) to select areas to be scanned at higher resolution and with more care—consistent with the intuitive scanning paradigm and the “unlimited resolution” offered by the proposed free-scan concept. Other signal processing paradigms can be used to accomplish the same purpose.

The fill and filter feature is introduced more as an aesthetic tool, it can often can lead to faster interpretation of scanned data with much fewer data points. The basic idea is to prevent the user frustration resulting from attempts to fill some few but scattered empty pixels. This tool also eliminates blocking effects when scanning at very low resolutions. This is accomplished using a suitable interpolation scheme followed by moving average filtering. Other signal processing paradigms can be used to accomplish the same purpose.

Most of the options related to the handling and displaying of the data can be changed by the user at any point using a graphical user interface (GUI). Briefly the options included are: scan area (through maximum and minimum limits obtained on each axis), maximum and minimum of display data to compress or stretch the color scale, interpolation threshold, filter size etc.

The inspection system described above demonstrates a different scanning method that has several advantages over existing eddy current inspection systems. The direct measurement of the magnetic flux density removes the need for complicated analysis on the received signal to detect the presence of defects. Using a GMR sensor for the field measurement allows for significant gains in sensitivity, as opposed to standard impedance coils. Use of the GMR sensor also allows for point measurement of the magnetic field, as opposed to a spatially averaged measurement as in the case of an impedance coil.

The demodulation circuit allows for an immense gain in the spatial resolution and the time required for the scan. The use of demodulation scheme with an automated scanner results in a direct relationship between spatial resolution and temporal sampling rate. Thus with high sampling rates it is possible to obtain very high spatial resolution, not supported by any current system. The demodulation scheme also paves way for the proposed free scan system, which is a new scanning paradigm.

The free scan approach makes the inspection process faster, efficient and accurate—all at the same time. The free scan introduces levels of intuitiveness and user friendliness in the inspection methodology never before achieved with any traditional scanning system. The system also allows for complete user control of the scan resolution resulting in a more accurate and higher resolution eddy current imaging method. The system allows the user to scan the sample at speeds that are much higher than conventional eddy current imaging systems. A complete prototype has been developed and implemented successfully. User-friendly and feature-rich software has also been developed for real time data display and storage. The prototype system is capable of detecting defects in experimental sample sets and outperforms the conventional scanning system in terms of efficiency and accuracy of the inspection process.

The inspection system can be employed to inspect large surfaces such as aircraft wings. Aircraft wings use a multilayered aluminum structure. The cyclical grading patterns on the wing contribute to the development and growth of cracks. In addition corrosion and other factor contribute to weakening of the structure. The proposed inspection system can be employed to detect corrosion and cracks in their incipient stages long before they become dangerous. However, it is envisioned that the proposed inspection system described herein can be used to inspect any conducting sample for surface and subsurface defects. The portability of system makes it an ideal choice for in-field inspections e.g. inspection of aircraft wing structures for sub-surface defects around the rivets. As mentioned earlier the concept of using demodulation based acquisition leading to “free scan” system can be applied to any nondestructive testing method based on continuous wave (cw) excitation. The above description is merely exemplary in nature and is not intended to limit the present disclosure, application, or uses.

What is claimed is:

1. A method for assessing structural integrity of a sample, comprising:
inducing an Eddy current in the sample using an excitation current signal;
capturing a signal indicative of magnetic flux density caused by the Eddy current in the sample;
extracting an envelope of the captured signal using a demodulation scheme;
sampling the envelope at a frequency that is lower than a frequency of the excitation current signal; and
examining the sampled envelope to assess structural integrity of the sample.

2. The method of claim 1 further comprises capturing a signal indicative of magnetic flux density using a giant magnetoresistive sensor.

3. The method of claim 1 further comprises extracting amplitude and phase from the captured signal using an in-phase/quadrature detection scheme.

4. The method of claim 1 further comprises implementing the demodulation scheme in an analog circuit.

5. The method of claim 1 further comprises identifying structural defects in the sample at locations where the sampled envelope exhibits variations in at least one of amplitude or phase.

6. The method of claim 1 further comprises sampling the envelope at a fixed frequency and generating a scan image from the sampled signal, where spatial resolution of the scan image is inversely proportional to speed at which the signal indicative of magnetic flux density was acquired.

7. An inspection system for assessing structural integrity of a sample, comprising:
a scanner freely movable along a surface of the sample, the scanner having a sensor operable to capture a signal indicative of magnetic flux density caused by an Eddy current flowing in the sample;
an amplitude demodulator adapted to receive the signal from the sensor and operable to extract a baseband signal from the signal from the sensor;
a signal processor operable to sample the baseband signal at a fixed sample rate and generate a scan image from the sampled baseband signal, where spatial resolution of the scan image is inversely proportional to speed at which the scanner is moved along the surface of the sample.

8. The inspection system of claim 7 wherein the scanner further includes means for inducing an Eddy current to flow in the sample.

9. The inspection system of claim 7 wherein the sensor in the scanner is further defined as a giant magnetoresistive sensor.

10. The inspection system of claim 7 wherein the amplitude demodulator is further defined as an in-phase/quadrature (I/Q) detector.

11. The inspection system of claim 7 wherein the amplitude is implemented in analog circuitry.

12. An inspection system for assessing structural integrity of a sample, comprising:
a scanner freely movable along a surface of the sample, the scanner having means for inducing an Eddy current to flow in the sample and a giant magnetoresistive (GMR) sensor operable to capture a signal indicative of magnetic flux density caused by an Eddy current flowing in the sample;
an amplitude demodulator adapted to receive the signal from the sensor and operable to extract a baseband signal from the signal; and
a signal processor operable to sample the baseband signal at a fixed frequency that is lower than a frequency of an excitation signal which generated the Eddy current flowing in the sample.

13. The inspection system of claim 12 wherein the amplitude demodulator is further defined as an in-phase/quadrature (I/Q) detector.

14. The inspection system of claim 12 wherein the amplitude is implemented in analog circuitry.

15. The inspection system of claim 12 wherein the signal processor is operable to generate a scan image from the sampled baseband signal, where spatial resolution of the scan image is inversely proportional to speed at which the scanner is moved along the surface of the sample.
